(19) United States
(12) Patent Application Publication
(10) Pub. No.: US 2015/0003636 A1
(43) Pub. Date: Jan. 1, 2015

(54) SCALABLE AND AUTOMATIC DISTANCE-BASED AUDIO ADJUSTMENT

(71) Applicant: Disney Enterprises, Inc., Burbank, CA (US)

(72) Inventor: Gregory Shear, Glendale, CA (US)

(21) Appl. No.: 13/928,294

(22) Filed: Jun. 26, 2013

(51) Int. Cl. H03G 3/20

(52) U.S. Cl. CPC H03G 3/20
USPC 381/107

(57) ABSTRACT

A computer program product, method, apparatus, and system determine location data of a performance. Further, the computer program product, method, and system provide the location data to an audio adjustment device that calculates a distance-based audio adjustment based upon a difference between a position of the performance indicated by the location data and a position of a speaker that is coupled to receive an audio signal from the audio adjustment device. The audio adjustment device adjusts at least one characteristic of the audio signal based upon the distance between the performance and the speaker.

### BACKGROUND

1. Field

This disclosure generally relates to the field of audio effects. More particularly, the disclosure relates to distance-based adjustments to audio effects.

2. General Background

In a live entertainment environment, it is desired that sound appears to be coming from a performer or an entertainment vehicle, such as a parade float. As a performer or an entertainment vehicle carrying a sound reinforcement device, e.g., amplifier, loudspeaker, or the like, is often not practical, audio effects are often played back through a set of speakers distributed around the entertainment environment area. When distributed speakers are used, if all of the speakers emit sound at the same volume, the audience will not experience the expected changes in volume that occur as the performer or vehicle move closer and farther away from the audience member. To address this, when a performer or entertainment vehicle moves within the entertainment area, an illusion is provided by adjusting the volume of speakers non-uniformly so that audience members hear the performer or entertainment vehicle approaching or moving away from the audience members. That illusion is provided by manually adjusting sound levels of sound reinforcement devices.

Until now, inaccuracies resulted from the manual sound adjustments. Workers had to manually track the location of a performer or an entertainment vehicle, which is not always feasible and introduces error. For instance, the performer or entertainment vehicle may enter a portion of the entertainment environment that is not readily visible to the worker performing the tracking. Further, various obstructions may interfere with such tracking ability. The workers typically also have to estimate multiple independent distances simultaneously, e.g., different distances between different locations at which the performers or entertainment vehicles are located from the audience members. Such independent estimations are often quite difficult for a worker to manually perform manually. For example, a person working at an audio mixer behind an audience may have much more difficulty adjusting the audio effects in multiple speakers for two or more performers moving around a stage than a single performer. A worker typically has significant difficulty focusing on multiple moving audio sources in addition to the quantity of knobs and/or faders that have to be adjusted for those multiple moving audio sources. Further, such estimations are often not based on a uniform approach, but rather a manual subjective assessment that may vary at the same distance tracked by the same worker.

Systems exist for synchronizing audio along a parade route, for example, between parade vehicles/performers and wayside speakers. These systems focus on selecting which performance is produced by a given speaker or set of speakers so that audio related to a particular vehicle or performer will be broadcast by speakers proximate to that vehicle or performer. As the parade progresses, the speakers switch from the completing performance to the next subsequent performance. These systems rely on some method to locate the vehicle/performance along the parade route. For instance, a vehicle has a wheel counter system that counts wheel rotations which can be used to determine the vehicle's location by a dead reckoning method so long as the vehicle is following a defined route. The dead reckoning location can be used by an audio router to direct audio associated with that vehicle to wayside speakers that are proximate to the vehicle. Such automated system lacks flexibility as the vehicle has to travel along a predetermined path to ensure that sounds are emitted at the intended times. For example, the vehicle's sounds may be emitted through incorrect speakers if the vehicle moves along an alternative path or varies too significantly from a mapped path. Improvements in audio effects systems are needed.

### SUMMARY

A computer program product, method, apparatus, and system determine location data of a performance. Further, the computer program product, method, and system provide the location data to an audio adjustment device that calculates a distance-based audio adjustment based upon a difference between a position of the performance indicated by the location data and a position of a speaker that is coupled to receive an audio signal from the audio adjustment device. The audio adjustment device adjusts at least one characteristic of the audio signal based upon the distance between the performance and the speaker.

### BRIEF DESCRIPTION OF THE DRAWINGS

The above-mentioned features of the present disclosure will become more apparent with reference to the following description taken in conjunction with the accompanying drawings wherein like reference numerals denote like elements and in which:

FIG. 1 illustrates a distance-based audio adjustment configuration that is based upon location tracking data.

FIG. 2A illustrates an alternative distance-based audio adjustment configuration.

FIG. 2B illustrates yet another alternative distance-based audio adjustment configuration.

FIG. 2C illustrates an alternative distance-based audio adjustment configuration that performs audio routing.

FIG. 2D illustrates a distance-based audio adjustment configuration that performs audio adjustments for multiple performances simultaneously.

FIG. 3 illustrates yet another alternative distance-based audio adjustment configuration.

FIG. 4 illustrates an expanded view of the location device.

### DETAILED DESCRIPTION

Live audio performances can originate from one or more human performances, machines and electronics, instruments, and the like. For ease of description, these are often referred to herein as a performance. In an exemplary live audio environment, a performance generates performed audio, which is processed, routed and amplified and then broadcast by distributed loudspeakers. The performed audio may be human or machine generated, and may be mixed with pre-recorded material or entirely pre-recorded material. Audio processing may occur at various stages and the components of a system in accordance with the present invention may be coupled by wired or wireless connections to suit the needs of a particular application and available technology. A location tracking device tracks location of a performance and provides location data to one or more audio adjustment devices. A distinct audio source, e.g., an audio source device, audio data, or the like, provides sound from a distinct location to that of the performance. The audio adjustment device adjusts an audio characteristic, e.g., sound volume, gain, delay, echo, reverberation, frequency filtering, or other spatially relevant audio characteristic, received from the audio source based upon the location data received from the location tracking device. As a result, precise location data may be utilized to automatically adjust audio based upon a distance from the performance to an intended location, e.g., speakers proximate to audience members. In operation, the audio produced by speakers can be controlled such that, for example, a performance sounds more faint and distant when it is farther away, and sounds louder and closer when the performance is nearer.

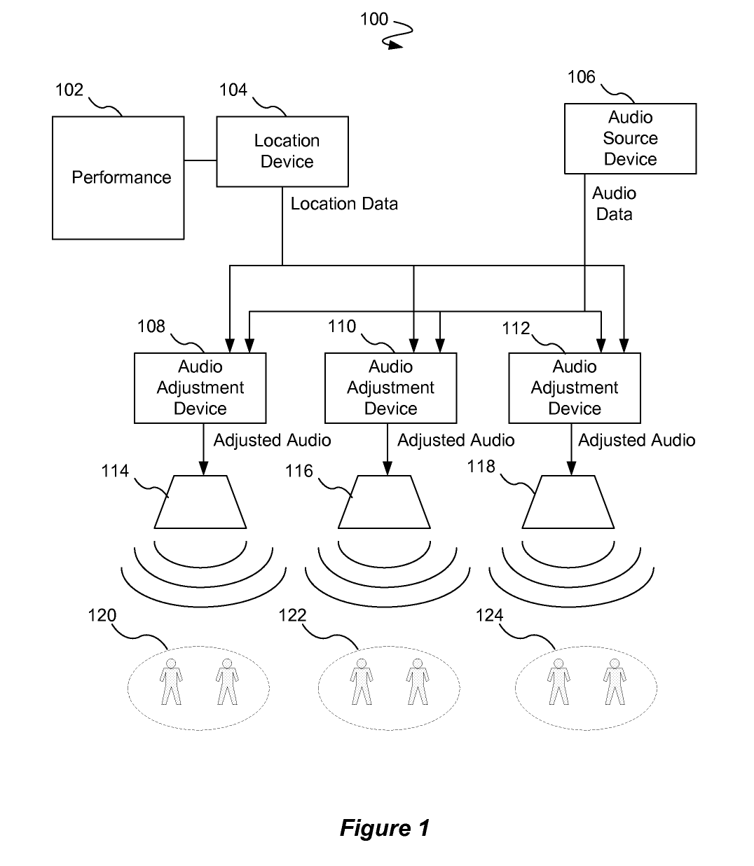

FIG. 1 illustrates a distance-based audio adjustment configuration 100 that is based upon location data. In one embodiment, a performance 102 produces performed audio. The performance 102 may be a human performance, costumed character, sound system mounted on a parade vehicle or other machine, instrument, animatronic, robot, mechanical device, or the like.

A location device 104 is in operable communication, e.g., wired, wireless, or the like, with the performance 102. The location device 104 determines the location of the performance 102. In an alternative embodiment, the location device 104 is integrated within the performance 102. In one embodiment, the location device 104 has a transmitter or is in operable communication with a transmitter that transmits the location data to a plurality of audio adjustment devices, e.g., 108, 110, and 112. The location device 104 may be based upon Global Positioning System (“GPS”) data, i.e., satellite based location and time information, image analysis, radio frequency triangulation, WiFi hotspot, cell tower location technology, a motion tracking system, or the like. The location data may latitude and longitude data, x and y coordinates, geocode data, or any other type of positioning data that the position of the performance.

In some implementations audio may be generated live at the performance 102 and coupled to the audio adjustment device(s) 108, 110 and 112 by wired or wireless connections. Alternatively or in addition, an audio source device 106 that is separate from but synchronized to the performance 102 provides audio to the plurality of audio adjustment devices, e.g., 108, 110, and 112. The audio source device 106 provides live and/or prerecorded audio content, typically audio content that is intended to appear as if it is generated at the location of performance 102.

The plurality of audio adjustment devices 108, 110, and 112 are each in operable communication with a respective speaker, e.g., 114, 116, and 118. Typically speakers 114, 116 and 118 are stationary. The plurality of audio adjustment devices 108, 110, and 112 are each preprogrammed with respective location data for each of the plurality of audio adjustment devices 108, 110, and 112. It is contemplated that mobile speakers may be used in some implementations in which case it is possible to use location devices (not shown) to provide location information of the mobile speakers to audio adjustment devices 108, 110 and 112. The speakers 114, 116 and 118 are each positioned in a particular area in proximity to various audience members, e.g., 120, 122, and 124. The plurality of audio adjustment devices 108, 110, and 112 is provided for illustration purposes. A single audio adjustment device or different quantities of audio adjustment devices may be utilized instead. In one implementation, an audio adjustment device comprises a digital signal processor (“DSP”).

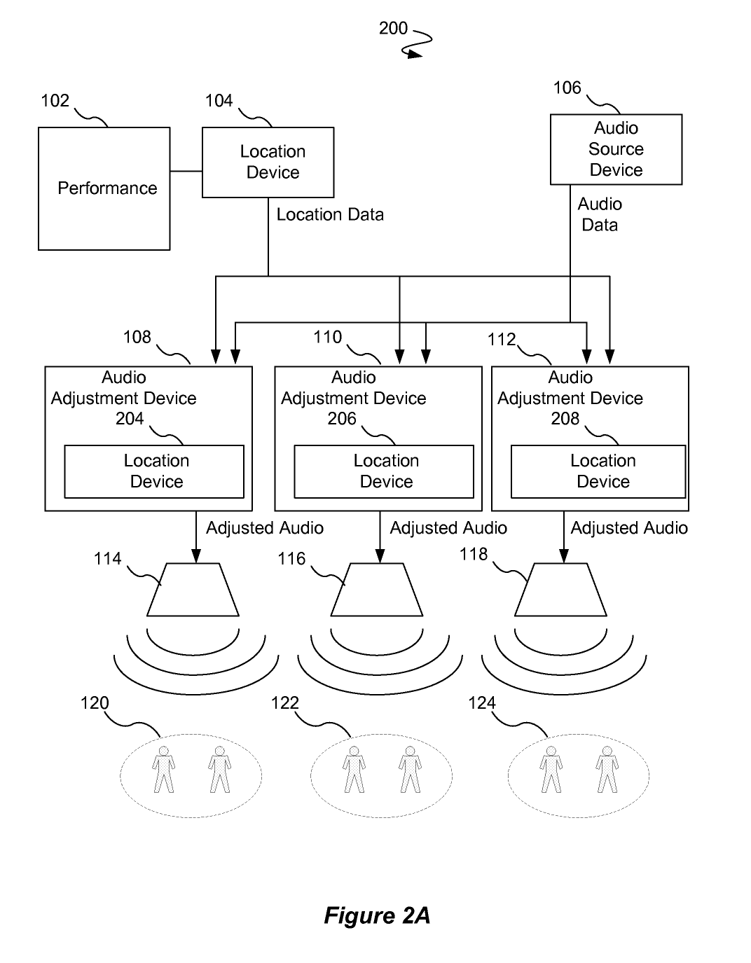

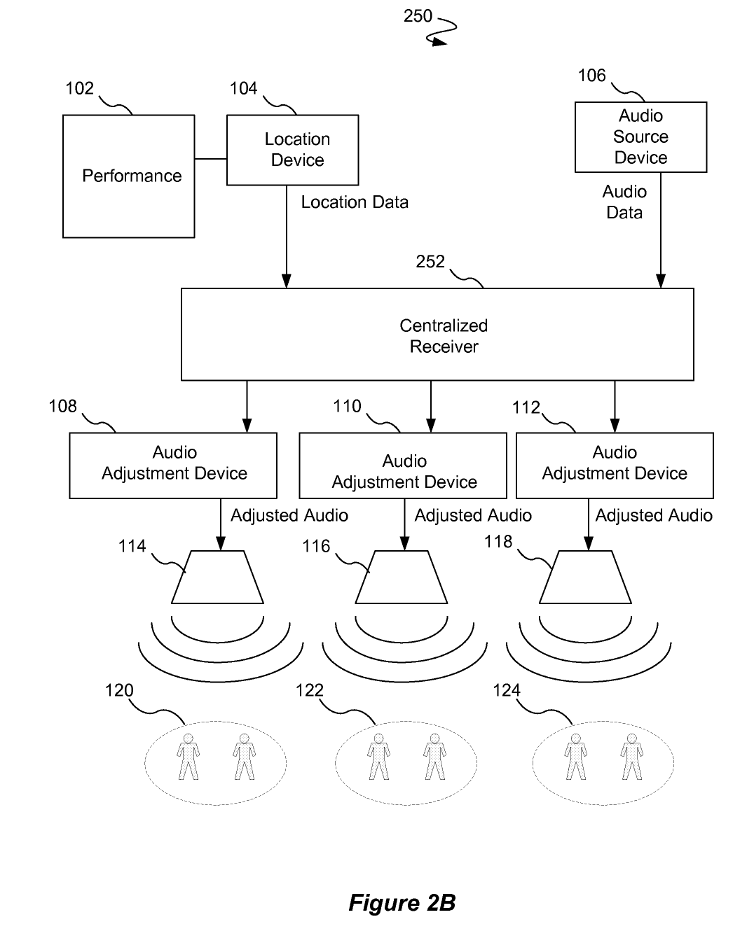

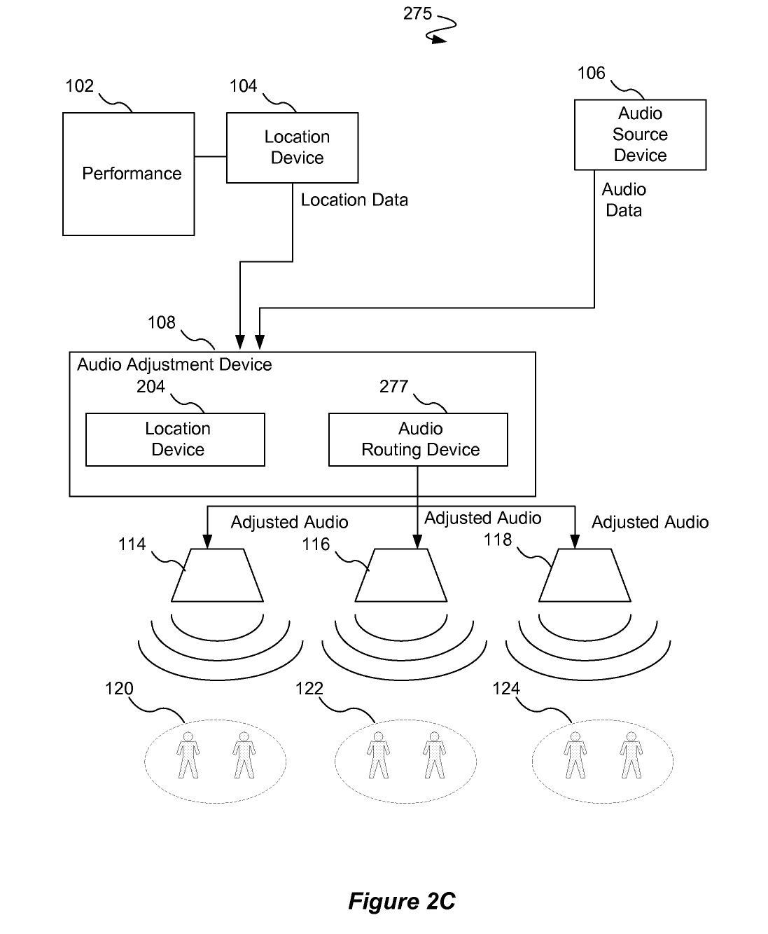

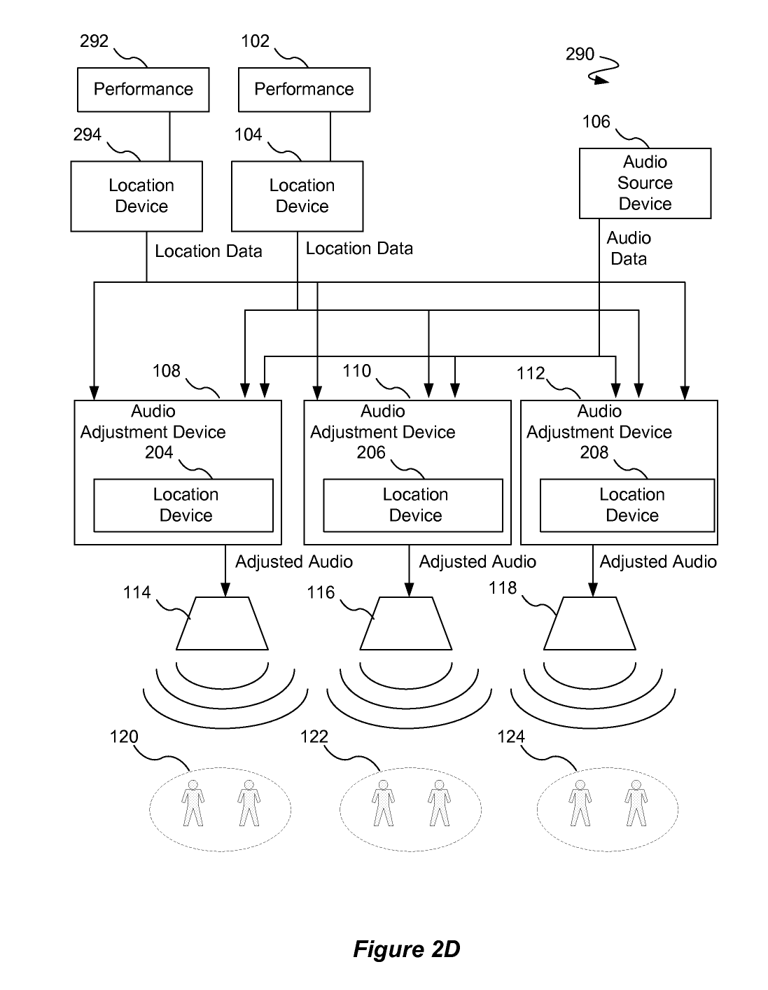

By receiving the location data of the performance 102 and the respective location data of the speakers 114, 116, and 118, the plurality of audio adjustment devices 108, 110, and 112 are each able to calculate the respective distance between the performance 102 and the corresponding speaker device. Based upon the calculated distance, each of the plurality of audio adjustment devices 108, 110, and 112 performs an audio adjustment that corresponds to the distance. FIG. 2A illustrates an alternative distance-based audio adjustment configuration 200. The distance-based audio adjustment configuration 200 has location devices 204, 206, and 208 that are integrated into the respective audio adjustment devices 108, 110, and 112. In contrast with the distance-based audio adjustment configuration 100 illustrated in FIG. 1 that utilizes audio adjustment devices 108, 110, and 112 and speakers 114, 116, and 118 that are fixed in position, the distance-based audio adjustment configuration 200 allows the audio adjustment devices 108, 110, and 112 and the speakers 114, 116, and 118 to be moved. In other words, the performance apparatus 102 may move while the audio adjustment devices 108, 110, and/or 112 in addition to the speakers 114, 116, and/or 118 are also in motion. The audio adjustment devices 108, 110, and/or 112 may be in close proximity to the speakers 114, 116, and/or 118 so that the locations of the audio adjustment devices 108, 110, and/or 112 are approximately the same as the locations of the corresponding speakers 114, 116, and/or 118. As the audio adjustment devices 108, 110, and 112 have tracking location information from respective location devices 204, 206, and 208 in addition to received location tracking information from the performance 102, the audio adjustment devices 108, 110, and 112 calculate the distance between the performance apparatus 102 and the respective speakers dynamically. As an example, the audio adjustment devices 108, 110, and 112 are positioned onto different vehicles along with corresponding speakers 114, 116, and 118 so that the audio adjustment devices 108, 110, and 112 along with the speakers 114, 116, and 118 are in motion in addition to the performance 102 being in motion. The audio source device 106 may or may not be in motion along with the audio adjustment devices 108, 110, and 112. Accordingly, a performance may be move to different locations. In other words, an audience may move from a particular location to a different location. The vehicles may move with the audience and generate the corresponding sound effects so that the audience hears the intended audio effects even if the performance 102 and the audience are in motion.

FIG. 2B illustrates yet another alternative distance-based audio adjustment configuration 250. A centralized receiver 252 receives the location data and the audio data. The centralized receiver implements the processes that calculate, e.g., with a processor, the audio adjustments based upon knowledge of the distance between performance 102 and the speakers 114, 116, and 118. The centralized receiver 252 then distributes the location and audio data to the respective speakers 114, 116, and 118. As a result, the individual audio adjustment devices 108, 110, and 112 do not have to perform the calculations to perform the audio adjustments.

FIG. 2C illustrates an alternative distance-based audio adjustment configuration 275 that performs audio routing. Rather than utilizing multiple audio adjustment devices as illustrated in FIG. 2A, the distance-based audio adjustment configuration 275 utilizes a single audio adjustment device 108 to perform audio adjustment. The audio adjustment device 108 then performs routing of various audio adjustments to corresponding speakers 114, 116, and 118. In one implementation, the audio adjustment device has an audio routing device 277 that routes the audio adjustments to the corresponding speakers 114, 116, and 118. The routing device 277 may be integrated within the audio adjustment device 108. Alternatively, the audio routing device 277 may be a distinct device that is in operable communication with the audio adjustment device 108.

Although a single performance 102 and a single location device 104 are illustrated in FIG. 1, multiple performances and corresponding location devices may be utilized for any of the configurations provided for herein. FIG. 2D illustrates a distance-based audio adjustment configuration 290 that performs audio adjustments for multiple performances simultaneously. For example, a performance 102 and a performance 292 may provide performances to the audience. The location device 104 provides location data for the performance 102 to the audio adjustment devices 108, 110, and 112 whereas the location device 292 provides location data for the performance 294 to the audio adjustment devices 108, 110, and 112. The audio adjustment devices 108, 110, and 112 may then simultaneously adjust the audio of the performance 102 and the performance 292. As a result, the distance-based audio adjustment configuration 290 provides for scalable audio adjustment that may be utilized to adjust audio for multiple performances, e.g., two or more performances, simultaneously. Such automatic simultaneous audio adjustment alleviates the difficulty of workers having to perform manual audio adjustments that are often too difficult to perform manually for multiple performances. Further, any of the configurations provided for herein are not limited to the size of a particular performance area. In other words, the configurations are scalable to larger and/or different performance areas without modifying the cumbersome changes to logic and/or code.

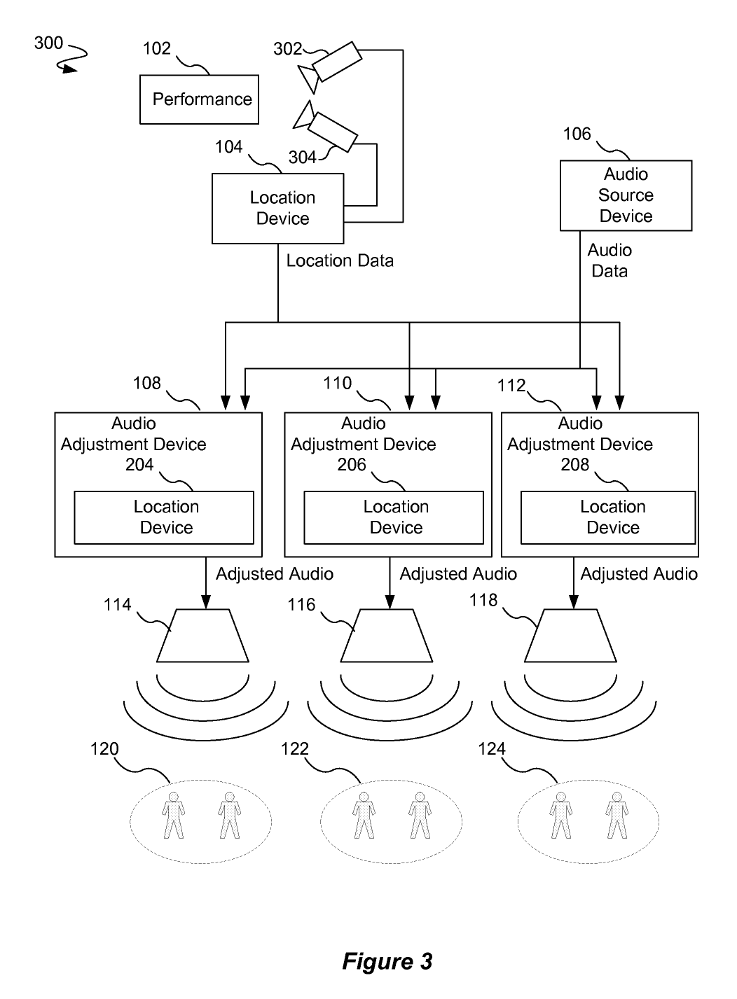

FIG. 3 illustrates yet another alternative distance-based audio adjustment configuration 300 in which the performance 102 is separate from location device 104. For example, an indoor entertainment environment such as a stage show, concert or theatrical production may not be conducive to certain location tracking technologies such as GPS. In these situations, external location tracking technology such as infrared, visible light, radio frequency or the like motion tracking can track the performance 102. A plurality of cameras, e.g., 302 and 304, perform motion capture of the performance 102 to provide images to the location device 104. Alternatively, the plurality of cameras 302 and 304 are integrated with the location device 104. Location device 104 analyzes the provided images using triangulation or other available techniques to determine location information for one or more objects of interest in performance 102 The audio adjustment devices 204, 206, and 208 use the location information location to determine the position of the performance 102 to then calculate the distance of the performance 102 based upon the location information.

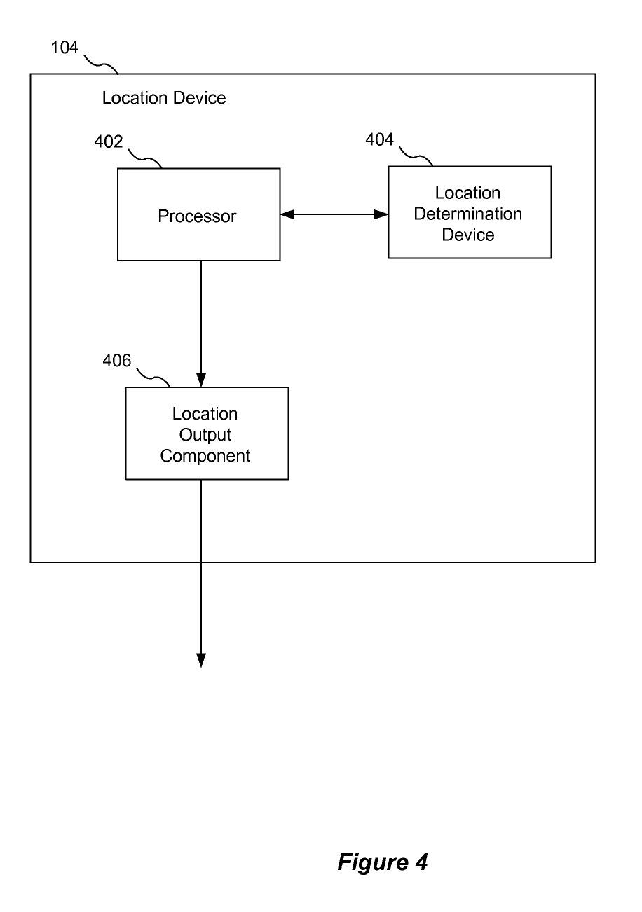

As shown in FIG. 4 location, the location device 104 may be any device that is capable of determining location data, e.g., a GPS device, image analysis, radio frequency triangulation, WiFi hotspot, cell tower location technology, a motion capture system, or the like. The location device 104 has a processor 402, a location determination device 404, and a output component 406. The processor 402 communicates with the location determination device 404 to determine a current location of the location device 104. As an example, the location determination device 404 is a GPS device that provides position coordinates of the location device 104 to the processor 402. The processor 402 then provides the position coordinates, e.g., latitude and longitude coordinates, to the output component 406. Alternatively, the location determination device 404 may be, an RF tag that can be located by triangulation or power measurements using an RF tag reader located at a reference position, or any available device that senses location with suitable accuracy and can provide the sensed location to processor 402.

In an alternative implementation, the location determination device 404 is separate from and in operable communication with the location device 104. As an example, the location determination device 404 is a motion capture system with at least one camera. The location determination device 404 sends the motion capture information to the location output component 406.

The processes described herein may be implemented in a general, multi-purpose or special purpose processor. Such a processor will execute instructions, either at the assembly, compiled or machine-level, to perform the processes. Those instructions can be written by one of ordinary skill in the art following the description herein and stored or transmitted on a computer readable medium. The instructions may also be created using source code or a computer-aided design tool. A computer readable medium may be any medium capable of carrying those instructions and include a CD-ROM, DVD, magnetic or other optical disc, tape, silicon memory (e.g., removable, non-removable, volatile or non-volatile), packetized or non-packetized data through wireline or wireless transmissions locally or remotely through a network. A computer is herein intended to include any device that has a general, multi-purpose or single purpose processor as described above. For example, a computer may be a personal computer (“PC”), laptop, smartphone, tablet device, set top box, or the like.

It is understood that the apparatuses, systems, computer program products, and processes described herein may also be applied in other types of apparatuses, systems, computer program products, and processes. Those skilled in the art will appreciate that the various adaptations and modifications of the aspects of the apparatuses, systems, computer program products, and processes described herein may be configured without departing from the scope and spirit of the present apparatuses, systems, computer program products, and processes. Therefore, it is to be understood that, within the scope of the appended claims, the present apparatuses, systems, computer program products, and processes may be practiced other than as specifically described herein.

I claim:

1. A computer program product comprising a computer readable storage device having a computer readable program stored thereon, wherein the computer readable program while executing on a computer causes the computer to:
determine location data of a performance; and
provide the location data to an audio adjustment device that calculates a distance-based audio adjustment based upon a difference between a position of the performance indicated by the location data and a position of a speaker that is coupled to receive an audio signal from the audio adjustment device, the audio adjustment device adjusting at least one characteristic of the audio signal based upon the distance between the performance and the speaker.

2. The computer program product of claim 1, wherein the performance is in motion.

3. The computer program product of claim 1, wherein the performance is temporarily motionless.

4. The computer program product of claim 1, wherein the at least one characteristic is selected from the group consisting of sound volume, gain, delay, echo, reverberation, and dynamic mix.

5. A method comprising:
determining location of an performance; and
providing the location to an audio adjustment device,
calculating a distance-based audio adjustment based upon a difference between apparatus position coordinates in the location data and speaker device coordinates of a speaker device that is in operable communication with an audio adjustment device, the audio adjustment device adjusting audio data based upon the distance-based audio adjustment.

6. The method of claim 5, wherein the performance is in motion.

7. The method of claim 5, wherein the performance is temporarily motionless.

8. The method of claim 5, wherein the location data is determined via a GPS device.

9. The method of claim 5, wherein the location data is determined via a motion capture system.

10. The method of claim 5, wherein the location data is determined via an RF system.

11. The method of claim 5, wherein the at least one characteristic is selected from the group consisting of sound volume, gain, delay, echo, reverberation, and dynamic mix.

12. A system comprising:
a processor;
a location device that determines location data of a performance; and
an output device that receives the location data from the processor and provides the location data to an audio adjustment device that calculates a distance-based audio adjustment based upon a difference between position of the performance indicated by the location data and position of a speaker that is coupled to receive an audio signal from the audio adjustment device.

13. The system of claim 12, wherein the location device is a GPS device.

14. The system of claim 12, wherein the location device is a motion capture device.

15. The system of claim 12, wherein the location device is an RF device.

16. The system of claim 12, wherein the speaker is remotely positioned from the distance-based audio adjustment device.

17. The system of claim 12, further comprising an audio switcher that routes audio signal.

18. An apparatus comprising:
an audio input that receives audio;
a location input that receives location data corresponding to a performance;
an audio adjustment device that calculates a distance-based audio adjustment based upon a difference between apparatus position coordinates in the location data and audio adjustment device position coordinates of an audio adjustment device, the audio adjustment device adjusting audio data based upon the distance-based audio adjustment.

19. The apparatus of claim 18, wherein the speaker is fixed.

20. The apparatus of claim 18, wherein the speaker is in motion.
